(19) United States
(12) Patent Application Publication
(10) Pub. No.: US 2021/0250007 A1
(43) Pub. Date: Aug. 12, 2021

(54) FULLY-DIFFERENTIAL VOLTAGE-CONTROLLED CURRENT SOURCE

(71) Applicant: Renesas Electronics America Inc., Milpitas, CA (US)

(72) Inventor: Martin SCHMIDT, Dresden (DE)

(73) Assignee: Renesas Electronics America Inc., Milpitas, CA (US)

(21) Appl. No.: 17/156,989

(22) Filed: Jan. 25, 2021

(30) Foreign Application Priority Data
Feb. 7, 2020 (EP) 20156056.2

(51) Int. Cl. H03F 3/45

(52) U.S. Cl. CPC H03F 3/45475; H03F 2203/45528; H03F 2200/129

(57) ABSTRACT

A current source having an operational amplifier with positive input, negative input, negative output and positive output, negative input voltage connected to the positive input via a negative input resistor, positive input voltage connected to the negative input via a positive input resistor, the negative output is connected to the positive input via a first negative feedback resistor and to the negative input via a series connection of a first current sense resistor and a first positive feedback resistor, the positive output is connected to the negative input via a second negative feedback resistor and to the positive input via a series connection of a second current sense resistor and a second positive feedback resistor, a negative load output is between the first current sense resistor and the first positive feedback resistor, and a positive load output is between the second current sense resistor and the second positive feedback resistor.

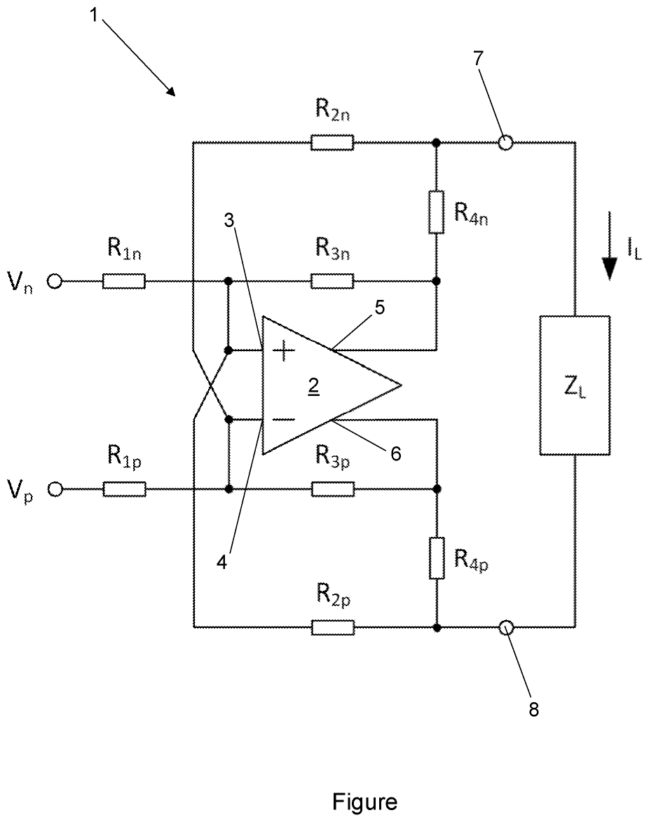

### CROSS-REFERENCE TO RELATED APPLICATIONS

The subject application claims priority to European Patent Application No. EP 20156056.2, filed on Feb. 7, 2020. The entire content of European Patent Application No. EP 20156056.2 is incorporated by reference herein.

### BACKGROUND

The invention relates to a fully-differential voltage-controlled current source.

Many electronic devices require a controlled current for operation. For example, an inductive sensor may require a controlled current to excite a primary coil of the inductive sensor. This function can be fulfilled by a voltage-controlled current source (VCCS), which principally is known from the prior art. An example of such a known VCCS is a so-called Improved Howland Current Source. However, the VCCSs known from the prior art require a grounded load and cannot provide a fully-differential output for an ungrounded load.

### SUMMARY

It is therefore an object of the present invention to provide a fully-differential voltage-controlled current source.

According to the invention the object is solved by a fully-differential voltage-controlled current source, comprising:

an operational amplifier with a positive input, a negative input, a negative output and a positive output,

wherein a negative input voltage is connected to the positive input of the operational amplifier via a negative input resistor and a positive input voltage is connected to the negative input of the operational amplifier via a positive input resistor,

wherein the negative output of the operational amplifier is connected to the positive input of the operational amplifier via a first negative feedback resistor and to the negative input of the operational amplifier via a series connection of a first current sense resistor and a first positive feedback resistor,

wherein the positive output of the operational amplifier is connected to the negative input of the operational amplifier via a second negative feedback resistor and to the positive input of the operational amplifier via a series connection of a second current sense resistor and a second positive feedback resistor, and

wherein a negative load output is provided between the first current sense resistor and the first positive feedback resistor and a positive load output is provided between the second current sense resistor and the second positive feedback resistor.

The operational amplifier of the fully-differential voltage-controlled current source is operated as a differential amplifier. The fully-differential voltage-controlled current source according to the invention regulates the differential current through the first current sense resistor and the second current sense resistor.

The operational amplifier and the described resistor network provide a fully-differential voltage-controlled current source with a high output impedance. Furthermore, the fully-differential voltage-controlled current source has a high robustness against electromagnetic interference (EMI). The differential output of the circuit behaves like a current source while the common mode voltage of the output is set by the amplifiers common mode feedback loop.

In a variant of the invention the negative input resistor is equal to the positive input resistor. Thus, the input impedance for the negative input voltage and the positive input voltage is identical.

According to a further variant of the invention the first positive feedback resistor is equal to the second positive feedback resistor. And in a further variant of the invention the first negative feedback resistor is equal to the second negative feedback resistor. Pursuant to another variant of the invention the first current sense resistor is equal to the second current sense resistor. The matching of the positive feedback resistors, the negative feedback resistors and the current sense resistors is important for a high output impedance of the current source.

In a further variant of the invention the first positive feedback resistor is equal to a series connection of the first negative feedback resistor and the first current sense resistor. According to a corresponding variant of the invention the second positive feedback resistor is equal to a series connection of the second negative feedback resistor and the second current sense resistor.

### BRIEF DESCRIPTION OF THE DRAWINGS

In the following the invention will be further explained with respect to the embodiment shown in the FIGURE.

The FIGURE shows a block diagram of a fully-differential voltage-controlled current source according to the invention.

### DETAILED DESCRIPTION

The FIGURE shows a block diagram of an embodiment of a fully-differential voltage-controlled current source 1 according to the invention. The fully-differential voltage-controlled current source 1 comprises an operational amplifier 2. The operational amplifier 2 is operated in a differential mode and has a positive input 3, a negative input 4, a negative output 5 and a positive output 6.

A negative voltage input Vₙ is connected to the positive input 4 of the operational amplifier 2 via a negative input resistor R₁ₙ. Likewise, a positive input voltage Vₚ is connected to the negative input 4 of the operational amplifier 2 via a positive input resistor R₁ₚ.

The negative output 5 of the operational amplifier 2 is connected to the positive input 3 of the operational amplifier 2 via a first negative feedback resistor R₃ₙ. The negative output 5 of the operational amplifier 2 is further connected to the negative input 4 of the operational amplifier 2 via a series connection of a first current sense resistor R₄ₙ and a first positive feedback resistor R₂ₙ. Particularly, the first current sense resistor R₄ₙ is connected to the negative output 5 of the operational amplifier 2 and the first positive feedback resistor R₂ₙ is connected to the negative input 4 of the operational amplifier 2. A negative load output 7 is provided between the first current sense resistor R₄ₙ and the first positive feedback resistor R₂ₙ.

The positive output 6 of the operational amplifier 2 is connected to the negative input 4 of the operational amplifier 2 via a second negative feedback resistor R₃ₚ. The positive output 6 of the operational amplifier 2 is further connected to the positive input 3 of the operational amplifier 2 via a series connection of a second current sense resistor R₄ₚ and a second positive feedback resistor R₂ₚ. Particularly, the second current sense resistor R₄ₚ is connected to the positive output 6 of the operational amplifier 2 and the second positive feedback resistor Rₑₚ is connected to the positive input 3 of the operational amplifier 2. A positive load output 8 is provided between the second current sense resistor R₄ₚ and the second positive feedback resistor R₂ₚ.

In general, the input resistor is referred to as R₁, the positive feedback resistor is referred to as R₂, the negative feedback resistor is referred to as R₃, and the current sense resistor is referred to as R₄.

The load Z_{L} is connected between the negative load output 7 and the positive load output 8. The fully-differential voltage-controlled current source 1 of the invention controls the current I_{L} through load Z_{L}. Load Z_{L} is for example an inductive sensor which requires a controlled current to excite a primary coil of the inductive sensor.

As can be seen from the FIGURE, the operational amplifier 2 and resistor network R₁, R₂, R₃, R₄ can be divided into a first upper side and a second lower side. The upper side is also referred to as negative side, indicated by indices n attached to the above-mentioned resistor references R₁ₙ, R₂ₙ, R₃ₙ, R₄ₙ. Likewise, the lower side is referred to as positive side, indicated by indices p attached to the above-mentioned resistor references R₁ₚ, R₂ₚ, R₃ₚ, R₄ₚ.

In the embodiment shown in the FIGURE, the negative input resistor R₁ₙ is equal to the positive input resistor R₁ₚ, the first positive feedback resistor R₂ₙ is equal to the second positive feedback resistor R₂ₚ, the first negative feedback resistor R₃ₙ is equal to the second negative feedback resistor R₃ₚ and the first current sense resistor R₄ₙ is equal to the second sense resistor R₄ₚ, resulting in:

R₁=R₁ₙ=R₁ₚ

R₂=R₂ₙ=R₂ₚ

R₃=R₃ₙ=R₃ₚ

R₄=R₄ₙ=R₄ₚ

Furthermore, the first positive feedback resistor R₂ₙ is equal to a series connection of the first negative feedback resistor R₃ₙ and the first current sense resistor R₄ₙ and the second positive feedback resistor R₂ₚ is equal to a series connection of the second negative feedback resistor R₃ₚ and the second current sense resistor R₄ₚ, resulting in:

R₂ₙ=R₃ₙ+R₄ₙ respectively

R₂ₚ=R₃ₚ+R₄ₚ or generally

R₂=R₃+R₄.

Considering the above, the transfer function of the fully-differential voltage-controlled current source 1 of the embodiment shown in the FIGURE is given by:

$$\frac{{I}_{L}}{{V}_{P} - {V}_{N}} = \frac{1}{2 {R}_{1}} ( 1 + \frac{{R}_{3}}{{R}_{4}} )$$

### LIST OF REFERENCE NUMERALS

1 fully-differential voltage-controlled current source
2 operational amplifier
3 positive input
4 negative input
5 negative output
6 positive output
7 negative load output
8 positive load output
Vₙ negative input voltage
Vₚ positive input voltage
Rₙ input resistor
R₁ₙ negative input resistor
R₁ₚ positive input resistor
R₂ positive feedback resistor
R₂ₙ first positive feedback resistor
R₂ₚ second positive feedback resistor
R₃ negative feedback resistor
R₃ₙ first negative feedback resistor
R₃ₚ second feedback resistor
R₄ current sense resistor
R₄ₙ first current sense resistor
R₄ₚ second current sense resistor
Z_{L} load
I_{L} load current

What is claimed is:

1. A fully-differential voltage-controlled current source comprising:
an operational amplifier with a positive input, a negative input, a negative output and a positive output,
wherein a negative input voltage is connected to the positive input of the operational amplifier via a negative input resistor and a positive input voltage is connected to the negative input of the operational amplifier via a positive input resistor,
wherein the negative output of the operational amplifier is connected to the positive input of the operational amplifier via a first negative feedback resistor and to the negative input of the operational amplifier via a series connection of a first current sense resistor and a first positive feedback resistor,
wherein the positive output of the operational amplifier is connected to the negative input of the operational amplifier via a second negative feedback resistor and to the positive input of the operational amplifier via a series connection of a second current sense resistor and a second positive feedback resistor, and
wherein a negative load output is provided between the first current sense resistor and the first positive feedback resistor and a positive load output is provided between the second current sense resistor and the second positive feedback resistor.

2. The fully-differential voltage-controlled current source according to claim 1,
wherein the negative input resistor is equal to the positive input resistor.

3. The fully-differential voltage-controlled current source according to claim 1,
wherein the first positive feedback resistor is equal to the second positive feedback resistor.

4. The fully-differential voltage-controlled current source according to claim 1,
wherein the first negative feedback resistor is equal to the second negative feedback resistor.

5. The fully-differential voltage-controlled current source according to claim 1,
wherein the first current sense resistor is equal to the second current sense resistor.

6. The fully-differential voltage-controlled current source according to claim 1,
wherein the first positive feedback resistor is equal to a series connection of the first negative feedback resistor and the first current sense resistor.

7. The fully-differential voltage-controlled current source according to claim 1,
wherein the second positive feedback resistor is equal to a series connection of the second negative feedback resistor and the second current sense resistor.
